(19) United States
(12) Patent Application Publication
(10) Pub. No.: US 2024/0234085 A9
(43) Pub. Date: Jul. 11, 2024

(54) METHOD FOR CREATING A SMOOTH DIAGONAL SURFACE USING A FOCUSED ION BEAM AND AN INNOVATIVE SCANNING STRATEGY

(71) Applicant: APPLIED MATERIALS ISRAEL LTD., Rehovot (IL)

(72) Inventor: Yehuda Zur, Tel-Aviv (IL)

(73) Assignee: APPLIED MATERIALS ISRAEL LTD., Rehovot (IL)

(21) Appl. No.: 17/972,427

(22) Filed: Oct. 24, 2022

(51) Int. Cl. H01J 37/305; H01J 37/147; H01J 37/28; H01L 21/263; H01L 21/304

(52) U.S. Cl. CPC H01J 37/305; H01J 37/1474; H01J 37/28; H01L 21/263; H01L 21/304; H01J 2237/0475; H01J 2237/31745; H01J 2237/31749

(57) ABSTRACT

A method of milling a diagonal cut in a region of a sample, the method comprising: positioning the sample in a processing chamber having a charged particle beam column; moving the region of the sample under a field of view of the charged particle column; generating a charged particle beam with the charged particle beam column and scanning the charged particle beam over the region of the sample along scan lines arranged parallel to a slope of the diagonal cut; and repeating the generating and scanning step a plurality of times to mill the diagonal cut in the region of the sample; wherein, for each iteration of the generating and scanning steps, a velocity of the charged particle beam is slower when the beam is near a deep end of the diagonal cut than when the beam is near a shallow end of the diagonal cut.

### BACKGROUND OF THE INVENTION

In the study of electronic materials and processes for fabricating such materials into an electronic structure, a specimen of the electronic structure can be used for microscopic examination for purposes of failure analysis and device validation. For instance, a specimen such as a silicon wafer that includes one or more electronic structures formed thereon can be milled and analyzed with a focused ion beam (FIB) to study specific characteristics of the structures formed on the wafer.

In recent years, there has been an emerging need to use diagonal surface milling as part of a metrology process. For example, when a sample is milled diagonally underlying layers at different depths can be imaged using a top view scanning electron microscope. For high precision of the metrology process, it is desirable that the milled diagonal surface be as smooth and straight as possible.

There are at least two different methods that have been used in the past to mill a desired diagonal surface. One such method relies on mechanically tilting the focused ion beam and milling the sample at an acute angle. For example, as shown in FIG. 1, which is a simplified side view of a known evaluation system 100, a focused ion beam column 110 can be tilted at an acute angle and direct an ion beam 120 towards a sample 130. A milling process can then be employed that creates a hole 140 in sample 130 that has a smooth bottom surface 142 with a uniform slope. As shown, surface 142 can extend from a surface 144 of the sample (i.e., the beginning of hole 140) and a deep end 146 (end) of the hole 140.

A second such method mills a diagonal cut by scanning the ion beam back and forth along a surface of the sample along scan lines that are perpendicular to the slope of the desired diagonal cut. This second method employs more passes of the ion beam in the deeper end of the diagonal cut thus milling more material in each iteration of the scan pattern towards the deeper than towards the shallower end. To illustrate, reference is made to FIGS. 2A and 2B where FIG. 2A depicts a scan pattern 210 and FIG. 2B is a simplified side view of a sample 230 that has a diagonal hole 220 milled in it. Scan pattern 210 can be used to mill the diagonally cut hole 220. The thicker lines of scan pattern 210 shown in FIG. 2A represent portions of the scan pattern that include more passes and thus mill a deeper portion of the hole 220 (e.g., in the vicinity of end portion 222). The thicker the line, the more passes of the focused ion beam in that portion of the scan pattern. The dashed lines indicate blanking steps in the milling process where the focal point of the ion beam is moved from the end of one scan line to the beginning of another scan line (e.g., as quickly as the system allows such). A milling process using the scan pattern shown in FIG. 2A can generate a smooth diagonal cut forming hole 220 shown in FIG. 2B.

Despite the availability of the above two methods for milling diagonal holes in a sample, new and improved methods are desirable.

### BRIEF SUMMARY OF THE INVENTION

Embodiments of the disclosure provide improved methods and a system for milling a diagonal cut in a sample. Embodiments of the disclosure can be employed to mill a sloped (diagonal) surface into a sample that is highly smooth and very straight. While embodiments of the disclosure can be used to delayer structures formed on a variety of different types of samples, some embodiments are particularly useful in delayering samples that are semiconductor wafers or similar specimens.

In some embodiments a method of milling a diagonal cut in a region of a sample can include: positioning the sample in a processing chamber having a charged particle beam column; moving the region of the sample under a field of view of the charged particle column; generating a charged particle beam with the charged particle beam column and scanning the charged particle beam over the region of the sample along scan lines arranged parallel to a slope of the diagonal cut; and repeating the generating and scanning step a plurality of times to mill the diagonal cut in the region of the sample. Where, for each iteration of the generating and scanning steps, a velocity of the charged particle beam can be set to be slower when the beam is near a deep end of the diagonal cut than when the beam is near a shallow end of the diagonal cut.

Some embodiments pertain to a system for milling a diagonal cut in a sample. The system can include: a vacuum chamber; a sample support configured to hold a sample within the vacuum chamber during a milling process; a charged particle beam column configured to direct a charged particle beam into the vacuum chamber; and a processor and a memory coupled to the processor. The memory can include a plurality of computer-readable instructions that, when executed by the processor, cause the system to position the sample in a processing chamber having a charged particle beam column; move the region of the sample under a field of view of the charged particle column; generate a charged particle beam with the charged particle beam column and scanning the charged particle beam over the region of the sample along scan lines arranged parallel to a slope of the diagonal cut; and repeat the generating and scanning step a plurality of times to mill the diagonal cut in the region of the sample. Where, for each iteration of the generating and scanning steps, a velocity of the charged particle beam can be set to be slower when the beam is near a deep end of the diagonal cut than when the beam is near a shallow end of the diagonal cut.

In some embodiments, a non-transitory computer-readable memory that stores instructions for milling a diagonal cut in a sample is provided. The instructions can include instructions for positioning the sample in a processing chamber having a charged particle beam column; moving the region of the sample under a field of view of the charged particle column; generating a charged particle beam with the charged particle beam column and scanning the charged particle beam over the region of the sample along scan lines arranged parallel to a slope of the diagonal cut; and repeating the generating and scanning step a plurality of times to mill the diagonal cut in the region of the sample. Where, for each iteration of the generating and scanning steps, a velocity of the charged particle beam can be set to be slower when the beam is near a deep end of the diagonal cut than when the beam is near a shallow end of the diagonal cut.

In various implementations, the method of milling a diagonal cut in a sample can include one or more of the following features. The charged particle column can be a focused ion beam (FIB) column and the charged particle beam can be a focused ion beam. The focused ion beam can be decelerated along scan lines at a first constant rate when the beam travels from the shallow end towards the deep end of the diagonal cut and accelerated along the scan lines at a second constant rate when beam travels from the deep end of the diagonal cut towards the shallow end. The first constant rate can be the opposite of the second constant rate. The focused ion beam can be directed towards the sample at an angle perpendicular to the sample. The focused ion beam column can be part of a SEM-FIB tool that has both a scanning electron microscope column and a focused ion beam column. The sample can be a semiconductor substrate.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIG. 1 is a simplified diagram illustrating a first previously known technique for milling a diagonal surface in a sample;

FIG. 2A is a simplified illustration of a scan pattern that can be employed to mill a sloped surface in a sample according to a second previously known technique for milling a diagonal surface in a sample;

FIG. 2B is a simplified side-view of a sample having a diagonal surface milled in the sample forming a hole having a sloped bottom surface;

FIG. 3 is simplified illustration of a sample evaluation system according to some embodiments of the disclosure;

FIG. 4 is a flowchart depicting steps associated with milling a sample according to some embodiments;

FIG. 5 is a simplified example of a scan pattern that can be used to mill a region on a sample according to some embodiments;

FIG. 6 is a simplified side perspective view of a sample having a diagonal surface milled in the sample forming a sloped hole in accordance with some embodiments; and

FIG. 7 is a simplified illustration of an area on a semiconductor wafer that can be milled according to some embodiments.

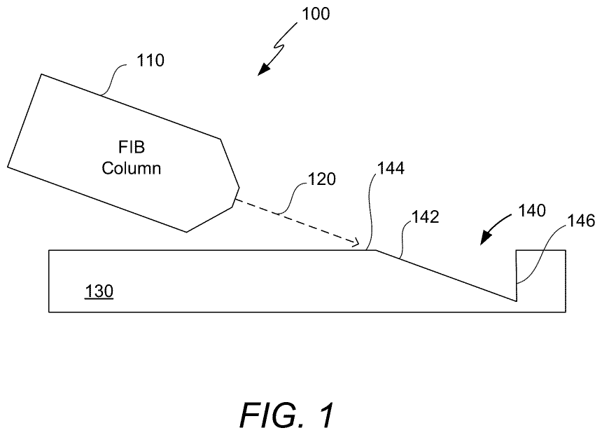

### DETAILED DESCRIPTION OF THE INVENTION

Embodiments of the disclosure provide improved methods and a system for milling a diagonal cut in a sample. Embodiments of the disclosure can be employed to mill a diagonal surface into a sample that is highly smooth and very straight. While embodiments of the disclosure can be used to delayer structures formed on a variety of different types of samples, some embodiments are particularly useful in delayering samples that are semiconductor wafers or similar specimens.

### Example Focused Ion Beam (FIB) Tool

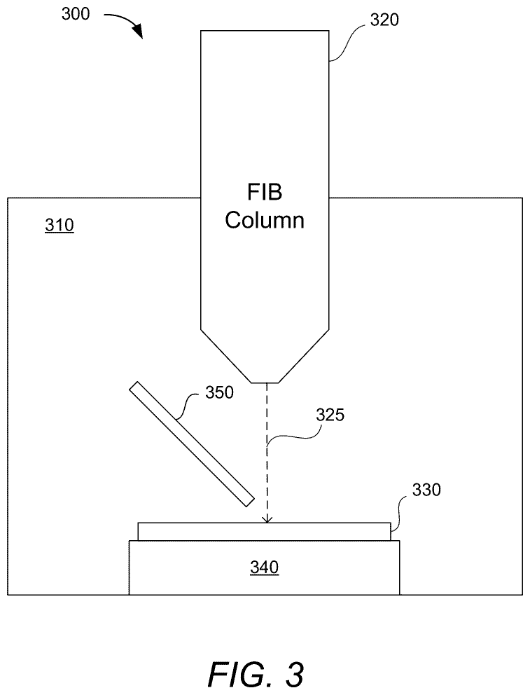

In order to better understand and appreciate the disclosure, reference is first made to FIG. 3, which is a simplified schematic illustration of a previously known focused ion beam (FIB) evaluation system 300. FIB system 300 can be used for, among other operations, milling a diagonal cut in a sample, such as a semiconductor wafer.

As shown in FIG. 3, system 300 can include, among other elements, a vacuum chamber 310 along with a focused ion beam (FIB) column 320. A supporting element 340 can support a sample 330 (e.g., a semiconductor wafer) within chamber 310 during a processing operation in which the sample 330 (sometimes referred to herein as an “object” or a “specimen”) is subject to a charged particle beam from FIB column 320.

During some processing operations, one or more gases can be optionally delivered into chamber 310 by a gas injection system 350. For simplicity of explanation gas injection system 350 is illustrated in FIG. 3 as a nozzle, but it is noted that gas injection system 350 can include gas reservoirs, gas sources, valves, one or more inlets and one or more outlets, among other elements. In some embodiments gas injection system 350 can be configured to deliver gas to a localized area of sample 330 that is exposed to the scan pattern of the charged particle beam as opposed to delivering gas to an entire upper surface of the sample. For example, in some embodiments gas injection system 350 has a nozzle opening diameter measured in hundreds of microns (e.g., between 400-500 microns) that is configured to deliver gas directly to a relatively small portion of the sample's surface that encompasses the charged particle beam scan pattern.

FIB column 320 is connected to vacuum chamber 310 so that the charged particle beam generated by the FIB column propagates through a vacuumed environment formed within vacuum chamber 310 before impinging on sample 330. For example, as shown in FIG. 3, FIB column 320 can generate a focused ion beam 325 that travels through the vacuum environment of chamber 310 before colliding with sample 330.

FIB column 320 can mill (e.g., drill a recess in) sample 330 by irradiating the sample with charged particle beam 325 to form a cross section and, if desired, can also smooth the cross section. An FIB milling process typically operates by positioning the specimen in a vacuum environment and emitting a focused beam of ions towards the specimen to etch or mill away material on the specimen. In some instances the vacuum environment can be purged by controlled concentration of background gases that serve to help control the etch speed and quality or help control matter deposition. The accelerated ions can be generated from Xenon, Gallium or other appropriate elements and are typically accelerated towards the specimen by voltages in the range from 500 volts to 100,000 volts, and more typically falling in the range from 3,000 volts to 30,000 volts. The beam current is typically in the range from several pico amps to several micro amps, depending on the FIB instrument configuration and the application, and the pressure is typically controlled between 10⁻¹⁰ to 10⁻⁵ mbar in different parts of the system and in different operation modes.

A milling process can be done by, for example: (i) locating a region of interest that should be milled in order to remove a portion (e.g., a portion of one or more layers) of material from the sample, (ii) moving the sample (e.g., by the mechanical supporting element 340) so that the sample is located under the field-of-view of the FIB unit, and (iii) milling the sample to remove a desired amount of material in the location of interest. The milling process can include forming a recess in the sample (usually sized a few microns to few hundreds of microns in the lateral dimensions), and in accordance with embodiments disclosed herein, the milling process can be performed to mill a diagonal surface into the sample.

The milling process typically includes scanning a charged particle beam back-and-forth (e.g., in a raster or other scan pattern) across a particular area of the sample being imaged or milled. One or more lenses (not shown) coupled to the charged particle column can implement the scan pattern as is known to those of skill in the art. The area scanned is typically a very small fraction of the overall area of sample. For example, the sample can be a semiconductor wafer with a diameter of 150, 200 or 300 mm while each area scanned on the wafer (i.e., the area milled) can be a rectangular area having a width and/or length measured in microns or tens of microns. Each iteration (or frame) in which the ion beam is scanned across the region being milled is typically measured in microseconds and removes a very small amount of material (e.g., as low as 0.01 atomic layers using a low i-probe (e.g., 10 pA) or as much as 1000 atomic layers using a high i-probe (e.g., 1000 nA)) such that the scan pattern is repeated many thousands or even millions of times to etch a hole to a desired depth.

During a milling operation the charged particle beam 320 generated by FIB column 320 propagates through the vacuumed environment formed within vacuum chamber 310 before impinging on sample 330. The milling process generates byproducts such as molecules, atoms and ions of the material being milled along with secondary electrons. For example, as an ion hits the sample surface with a relatively high energy level, the ion can begin a collision cascade that transfers momentum and energy from the ion to the sample until the ion is stopped and implanted. The momentum and energy transfer during the collision cascade can cause the dislocation of atoms, the ionization of atoms and the generation of phonons (heat). The cascade can reach the sample surface causing the sputtering of atoms having enough momentum and energy to escape the solid sample and generating secondary ions and electrons as a combination of ionization and sputtering that also escape the sample surface. The secondary ions or secondary electrons can be detected by an appropriate detector (not shown). The detected secondary ions or secondary electrons can then be used to analyze characteristics of the milled layers and the structure.

While not shown in FIG. 3, FIB system 300 can include one or more controllers, processors or other hardware units that control the operation of system 300 by executing computer instructions stored in one or more computer-readable memories as would be known to persons of ordinary skill in the art. By way of example, the computer-readable memories can include a solid-state memory (such as a random access memory (RAM) and/or a read-only memory (ROM), which can be programmable, flash-updateable and/or the like), a disk drive, an optical storage device or similar non-transitory computer-readable storage mediums.

As described below, embodiments in accordance with the present invention can implement a novel scanning process that can mill a diagonal surface in sample.

### Optimized Scan Pattern for Diagonal Milling

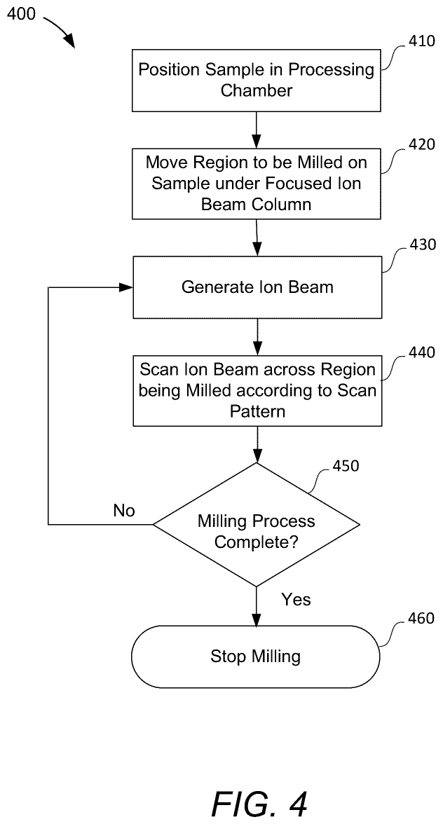

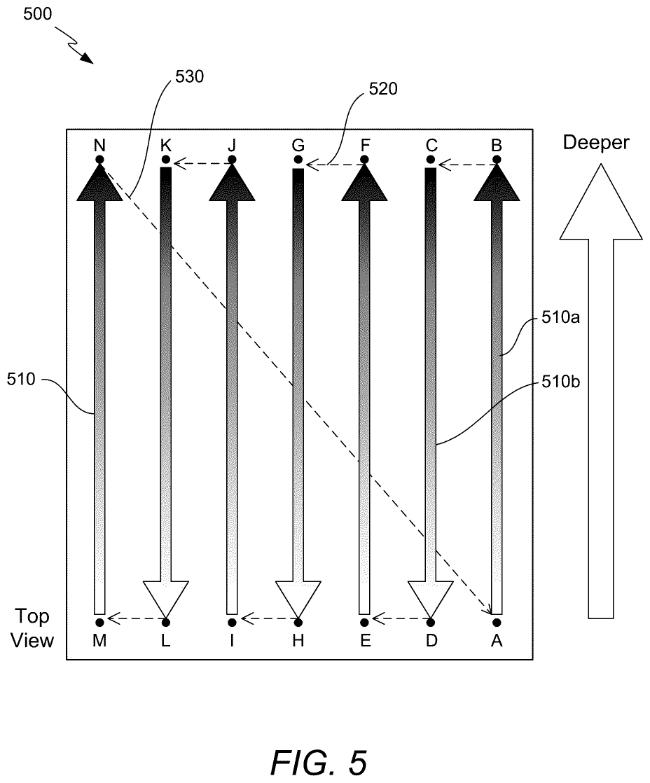

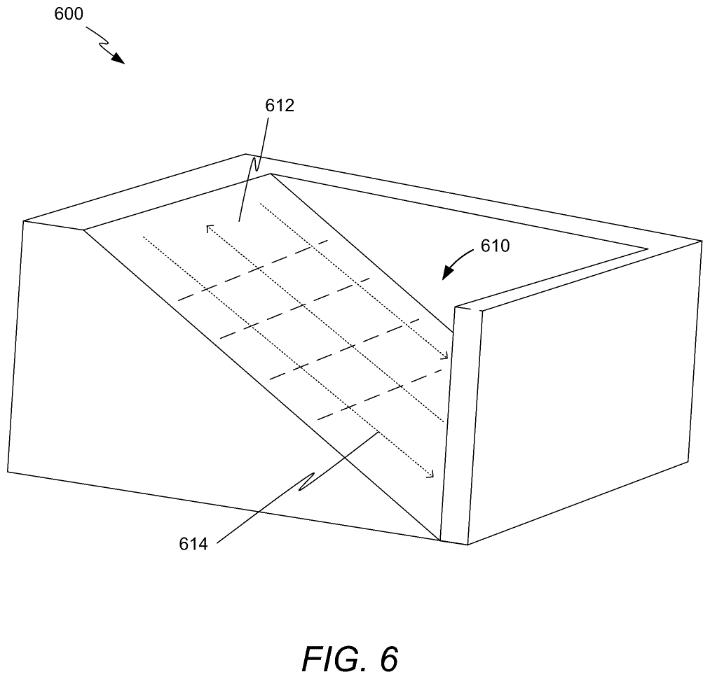

Embodiments described herein can mill a diagonal cut into a sample using a scan pattern that is optimized for diagonal milling. To illustrate, reference is made to FIGS. 4, 5 and 6. FIG. 4 is a flowchart depicting steps associated with a method 400 of milling a diagonal cut into a sample. FIG. 5 is a simplified top view of a scan pattern 500 according to some embodiments disclosed herein, and FIG. 6 is a simplified cross-sectional view of a sample 600 in which a hole having a diagonally milled surface is formed by milling the sample in accordance with method 400 and scan pattern 500.

Method 400 starts by positioning a sample within a processing chamber of a sample evaluation system (block 410). The processing chamber, which can be, for example, chamber 300, can include one or more charged particle beam columns that can be operated to mill a hole within a sample, such as sample 600, in one or more localized regions. Block 410 can include positioning sample 600 within the vacuum chamber on a surface of a sample support, such as support 140.

Next, support 140 can be moved within the processing chamber to position such that the region to be milled is placed within a field of view of a charged particle column, such as a focused ion beam (FIB) column 110. A charged particle beam (e.g., an ion beam) can then be generated (step 430) and focused and scanned across the region being milled on the sample (step 440). The charged particle beam can be focused by a focusing lens and scanned across a region of the substrate with one or more deflecting lenses (not shown) to mill a diagonal cut in the sample forming a hole having a sloped (diagonal) surface that is highly smooth and very straight, such as hole 610 milled in sample 600 shown in FIG. 6. In actual implementation, steps 430 and 440 can occur essentially simultaneously and very fast and, as discussed below, the ion beam is repeatedly stopped and restarted at different points in time (coinciding with the beam location in the scan pattern) as the scan pattern is followed.

Referring to FIG. 5, scan pattern 500 is one example of a scan pattern that can be employed in step 440 to mill a diagonal surface in a sample. As shown in FIG. 5, scan pattern 500 includes milling segments 510 (represented by solid scan lines) during which an ion beam is generated and directed to collide with the sample and blanking segments 520, 530 (represented by dashed lines) during which the focal point of the focused ion beam column is moved from the end of one scan line to the beginning of the next scan line. In each implementation of scan pattern 500, the focal point of the charged particle column travels from point A, to point B, to point C, to point D, etc. until it reaches point N at which time the focal point returns to point A and the scan pattern can be repeated. Embodiments generate an ion beam along each of the scan lines 510 and pause the ion beam as the focal point of the column traverses between scan lines along the blanking segments 520 and the return segment 530.

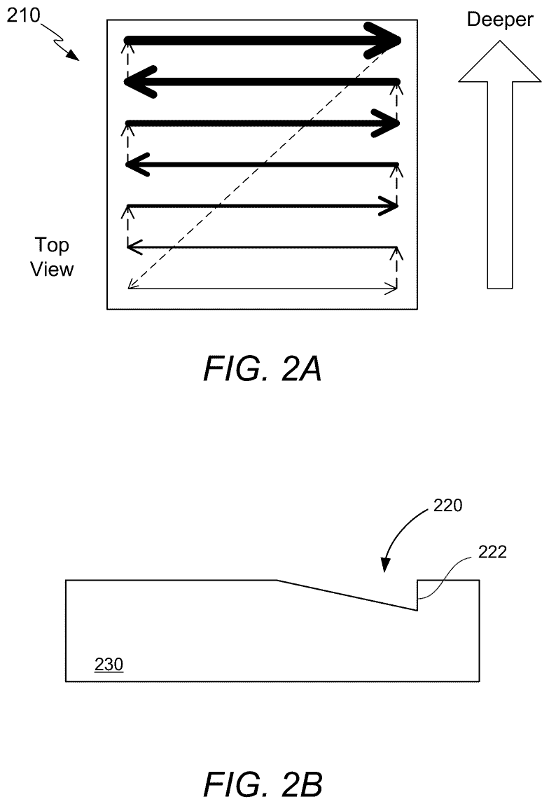

Scan pattern 500 differs from scan pattern 210 discussed above with respect to FIGS. 2A and 2B in several fundamental ways. First, as mentioned above scan pattern 210 includes individual scan lines that are perpendicular to the slope of the hole being milled. In contrast, and as illustrated in FIG. 6, the individual scan lines in scan pattern 500 are parallel to the slope of the hole being milled. For example, when scan pattern 500 is used to mill hole 610 shown in FIG. 6, scan lines 510 are aligned with the slope of hole 610 as represented by the three dotted lines 614 that extend between the top and bottom portions of hole 610. In contrast, the direction of scan lines in scan pattern 210 are perpendicular to the slope of the hole 220 being milled. Note, that while scan pattern 500 is depicted as having seven scan lines, this is for ease of illustration only. It is to be understood that embodiments disclosed herein are not limited to any particular number of scan lines in a scan pattern and, in actual implementation, a typical scan pattern employed to mill a sloped hole, such as hole 610, can include many more scan lines (e.g., hundreds or thousands of scan lines) than what is depicted in scan pattern 500.

During each pass of the scan pattern (i.e., each implementation of step 440), a very small amount of material is removed from the upper surface of the sample. In order to mill a diagonal cut into the sample, embodiments disclosed herein remove slightly more material when the focused ion beam is in the vicinity of the deeper end of the hole in each pass. To do such, embodiments vary the velocity of the focused ion beam in each scan line 510 during each execution of each scan pattern. In some embodiments the focused ion beam is scanned at a constant acceleration rate within each line instead of at a constant velocity. Thus, the velocity of the ion beam can vary along the scan line from a relatively fast velocity in the area of the hole being milled that is shallow to a relatively slow velocity in the area of the hole being milled that is deep. FIG. 5 depicts the changes in velocity of the focused ion beam along each scan line with changes in the fill color of each line where the darker color (at the deeper end of the milled region) represents a slower velocity of the ion beam than the lighter color (at the shallow end of the milled region).

In embodiments where the rate of acceleration is constant along the scan line, the change in velocity is linear. For example, as the ion beam travels from point A to point B, the beam is decelerated at a constant rate until it is paused at point B. The ion beam is reinitiated at point C and accelerated at a constant rate until it is paused again at point D. This pattern can repeat itself along each adjacent set of scan lines until the ion beam traverses the entire scan pattern 500. In some embodiments, the rate of deceleration as the beam travels from point A to point B is equivalent to the rate of acceleration as the beam travels from point C to point D. This ensure that the slope of the milled diagonal line is uniform resulting in a flat (straight) slope at the bottom surface of the milled region along the entirety of the hole being milled.

Because each implementation of scan pattern 500 removes only a very, very thin portion of the sample, the charged particle beam can be scanned across the region being milled multiple times (e.g., hundreds or thousands of times) to remove additional material (block 450) until a desired depth of the milling process indicating the milling process is complete (block 460). Once the milling process is complete, sample 600 will include a milled region 610 that has a diagonal, sloped surface 612.

### Example of a Sample to be Milled

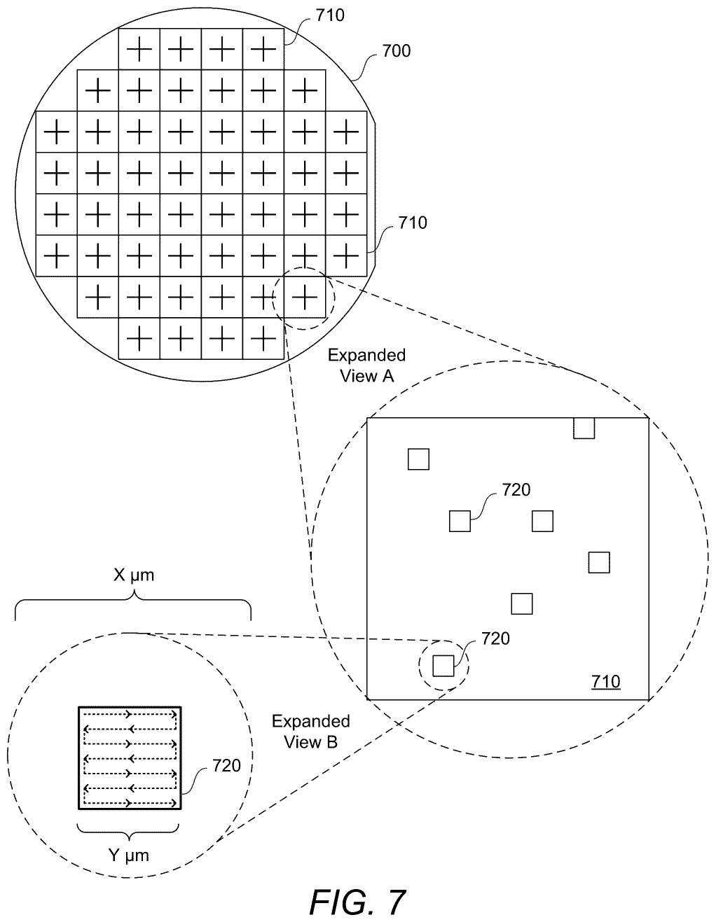

As stated above, embodiments of the disclosure can be used to mill a smooth diagonal cut in a sample forming a hole having a unform, sloped bottom surface. Embodiments can be used to mill such holes within many different types of samples including electronic circuits formed on semiconductor structures, solar cells formed on a polycrystalline or other substrate, nanostructures formed on various substrates and the like. As one non-limiting example, FIG. 7 is a simplified illustration of an area on a semiconductor wafer that can be milled according to some embodiments. Specifically, FIG. 7 includes a top view of wafer 700 along with two expanded views of specific portions of wafer 700. Wafer 700 can be, for example, a 150 mm, 200 mm or 300 mm semiconductor wafer and can include multiple integrated circuits 710 (fifty two in the example depicted) formed thereon. The integrated circuits 710 can be at an intermediate stage of fabrication and the milling techniques described herein can be used to evaluate and analyze one or more regions 720 of the integrated circuits

Embodiments of the disclosure can analyze and evaluate region 720 by sequentially milling away material within the region forming a diagonal cut as described above. The milling process can mill region 720 by scanning the FIB back and forth within the region according to a raster pattern, such as the scan pattern 500 discussed above with respect to FIG. 5, until the hole has been milled to a desired depth (with the desired slope).

### Additional Embodiments

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. For example, while the embodiments above described a focused ion column as part of a tool having a single charged particle column, in some embodiments the focused ion beam column can be part of a SEM-FIB tool that has both a scanning electron microscope column and a focused ion beam column.

Also, while different embodiments of the disclosure were disclosed above, the specific details of particular embodiments may be combined in any suitable manner without departing from the spirit and scope of embodiments of the disclosure. Further, it will be apparent to one of ordinary skill in the art that many modifications and variations are possible in view of the above teachings. It is, therefore, to be understood that the appended claims are intended to cover all such modifications and changes as fall within the true spirit of the embodiments of the disclosure.

Additionally, any reference in the specification above to a method should be applied mutatis mutandis to a system capable of executing the method and should be applied mutatis mutandis to a computer program product that stores instructions that once executed result in the execution of the method. Similarly, any reference in the specification above to a system should be applied mutatis mutandis to a method that may be executed by the system should be applied mutatis mutandis to a computer program product that stores instructions that can be executed by the system; and any reference in the specification to a computer program product should be applied mutatis mutandis to a method that may be executed when executing instructions stored in the computer program product and should be applied mutandis to a system that is configured to executing instructions stored in the computer program product.

Also, where the illustrated embodiments of the present disclosure can, for the most part, be implemented using electronic components and circuits known to those skilled in the art, details of such are not be explained in any greater extent than that considered necessary as illustrated above, for the understanding and appreciation of the underlying concepts of the present disclosure and in order not to obfuscate or distract from the teachings of the present disclosure.

What is claimed is:

1. A method of milling a diagonal cut in a region of a sample, the method comprising:
positioning the sample in a processing chamber having a charged particle beam column;
moving the region of the sample under a field of view of the charged particle column;
generating a charged particle beam with the charged particle beam column and scanning the charged particle beam over the region of the sample along scan lines arranged parallel to a slope of the diagonal cut; and
repeating the generating and scanning step a plurality of times to mill the diagonal cut in the region of the sample;
wherein, for each iteration of the generating and scanning steps, a velocity of the charged particle beam is slower when the beam is near a deep end of the diagonal cut than when the beam is near a shallow end of the diagonal cut.

2. The method of milling a diagonal cut in a sample as set forth in claim 1 wherein the charged particle column is a focused ion beam (FIB) column and the charged particle beam is a focused ion beam.

3. The method of milling a diagonal cut in a sample as set forth in claim 2 wherein the focused ion beam is decelerated along scan lines at a first constant rate when the beam travels from the shallow end towards the deep end of the diagonal cut and accelerated along the scan lines at a second constant rate when beam travels from the deep end of the diagonal cut towards the shallow end.

4. The method of milling a diagonal cut in a sample as set forth in claim 3 wherein the first constant rate is the opposite of the second constant rate.

5. The method of milling a diagonal cut in a sample as set forth in claim 2 wherein the focused ion beam is directed towards the sample at an angle perpendicular to the sample.

6. The method of milling a diagonal cut in a sample as set forth in claim 2 wherein the focused ion beam column is part of a SEM-FIB tool that has both a scanning electron microscope column and a focused ion beam column.

7. The method of milling a diagonal cut in a sample as set forth in claim 1 wherein the sample is a semiconductor substrate.

8. A system for milling a diagonal cut in a sample, the system comprising:
a vacuum chamber;
a sample support configured to hold a sample within the vacuum chamber during a milling process;
a charged particle beam column configured to direct a charged particle beam into the vacuum chamber;
a processor and a memory coupled to the processor, the memory including a plurality of computer-readable instructions that, when executed by the processor, cause the system to:
position the sample in a processing chamber having a charged particle beam column;
move the region of the sample under a field of view of the charged particle column;
generate a charged particle beam with the charged particle beam column and scanning the charged particle beam over the region of the sample along scan lines arranged parallel to a slope of the diagonal cut; and
repeat the generating and scanning step a plurality of times to mill the diagonal cut in the region of the sample;
wherein, for each iteration of the generating and scanning steps, a velocity of the charged particle beam is slower when the beam is near a deep end of the diagonal cut than when the beam is near a shallow end of the diagonal cut.

9. The system for milling a diagonal cut in a sample set forth in claim 8 wherein the charged particle column is a focused ion beam (FIB) column and the charged particle beam is a focused ion beam.

10. The system for milling a diagonal cut in a sample set forth in claim 9 wherein the focused ion beam is decelerated along scan lines at a first constant rate when the beam travels from the shallow end towards the deep end of the diagonal cut and accelerated along the scan lines at a second constant rate when beam travels from the deep end of the diagonal cut towards the shallow end.

11. The system for milling a diagonal cut in a sample set forth in claim 10 wherein the first constant rate is the opposite of the second constant rate

12. The system for milling a diagonal cut in a sample set forth in claim 9 wherein the focused ion beam is directed towards the sample at an angle perpendicular to the sample.

13. The system for milling a sample a diagonal cut in a sample set forth in claim 9 wherein the focused ion beam column is part of a SEM-FIB tool that has both a scanning electron microscope column and a focused ion beam column.

14. The system for milling a diagonal cut in a sample set forth in claim 8 wherein the sample is a semiconductor substrate.

15. A non-transitory computer-readable memory that stores instructions for milling a diagonal cut in a sample by:
positioning the sample in a processing chamber having a charged particle beam column;
moving the region of the sample under a field of view of the charged particle column;
generating a charged particle beam with the charged particle beam column and scanning the charged particle beam over the region of the sample along scan lines arranged parallel to a slope of the diagonal cut; and
repeating the generating and scanning step a plurality of times to mill the diagonal cut in the region of the sample;
wherein, for each iteration of the generating and scanning steps, a velocity of the charged particle beam is slower when the beam is near a deep end of the diagonal cut than when the beam is near a shallow end of the diagonal cut.

16. The non-transitory computer-readable memory that stores instructions for milling a diagonal cut in a sample set forth in claim 15 wherein the charged particle column is a focused ion beam (FIB) column and the charged particle beam is a focused ion beam

17. The non-transitory computer-readable memory that stores instructions for milling a diagonal cut in a sample set forth in claim 16 wherein the focused ion beam is decelerated along scan lines at a first constant rate when the beam travels from the shallow end towards the deep end of the diagonal cut and accelerated along the scan lines at a second constant rate when beam travels from the deep end of the diagonal cut towards the shallow end

18. The non-transitory computer-readable memory that stores instructions for milling a diagonal cut in a sample set forth in claim 17 wherein the first constant rate is the opposite of the second constant rate

19. The non-transitory computer-readable memory that stores instructions for milling a diagonal cut in a sample set forth in claim 16 wherein the focused ion beam is directed towards the sample at an angle perpendicular to the sample.

20. The non-transitory computer-readable memory that stores instructions for milling a diagonal cut in a sample set forth in claim 16 wherein the focused ion beam column is part of a SEM-FIB tool that has both a scanning electron microscope column and a focused ion beam column.
